(19) United States
(12) Patent Application Publication
(10) Pub. No.: US 2004/0040662 A1
(43) Pub. Date: Mar. 4, 2004

(54) Plasma processing method and apparatus for etching nonvolatile material

(76) Inventors: Manabu Edamura, Chiyoda (JP); Seiichiro Kanno, Chiyoda (JP); Ryoji Nishio, Kudamatsu (JP); Ken Yoshioka, Hikari (JP); Saburou Kanai, Hikari (JP); Tadamitsu Kanekiyo, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/229,076

(22) Filed: Aug. 28, 2002

(51) Int. Cl. H01L 21/306

(52) U.S. Cl. 156/345.48

(57) ABSTRACT

A plasma processing apparatus having a process chamber, a process gas feeding pipe for introducing a process gas into the process chamber, a holding electrode for receiving and holding a sample placed in the process chamber, a bias-potential-generating radio-frequency power source for supplying a bias potential to the sample, and an induction coil to produce a plasma, wherein the process chamber comprises a conductor member, disposed to face a portion of an internal surface of the process chamber, for supplying a bias potential to the portion, and a detachable trap member having a surface for deposition of reaction products formed at another portion of the internal surface of the process chamber.

### BACKGROUND OF THE INVENTION

The present invention relates to a plasma processing method and apparatus for etching non-volatile materials, and more particularly to a plasma processing method and apparatus for etching non-volatile etching materials with a low vapor pressure of reaction products.

As the component density is constantly growing in the semiconductor devices, LSIs among others, the design rule is moving toward under-submicron levels. Accordingly, the width of the internal wiring patterns is becoming narrower. For the internal wiring patterns of the semiconductor devices, heavily-doped polysilion or Al-based metals have been in widespread use. With the internal wiring materials such as these, because the wiring resistance is increased by the continuing reductions in the wiring width, problems have arisen, such as delays in signal propagation and decreases in migration resistance properties. To solve those problems, low-resistance metal wiring materials are being adopted, such as Cu metal, an Al—Cu alloy, or an Al—Si—Cu alloy.

In recent years, there have been proposed next-generation LSIs using a ferromagnetic film, such as lead titanate, [PbTiO₃], PZT [Pb (Zr, Ti)O₃], or PLZT [(Pb, La) (Zr, Ti)₃] as a dielectric material. DRAMs that have memory cells utilizing the ferroelectricity of those materials or FRAMs (Ferroelectric RAMs) of non-volatile memory type have been realized at a trial manufacture level or some of them have been put into commercial production. In the practical application of those ferroelectric devices, it is important to develop technology for patterning electrodes of ferroelectric films as well as a method for forming ferroelectric films with outstanding characteristics. Pt metals have often been used as an electrode material on a ferroelectric film from the viewpoint of realizing the stability of electrical characteristics.

For novel non-volatile memory LSIs utilizing the magnetic properties of materials, represented by MRAMs (Magnetic Random Access Memory), iron-based materials, such as Fe or Ni—Fe system, are used. Exotic material films, such as Ru and Ir, are being introduced one after another to accomplish next-generation LSI devices.

To form miniscale electrodes or wiring patterns by patterning of a Cu-based metal or a Pt- or Fe-based material, plasma etching, which chiefly uses a halogen gas, such as a chlorine gas, is adopted. Plasma etching is a technique of etching a processing object with incident ions and reactive neutral radicals.

In the course of the advancement of LSI manufacturing technology, plasma etching has played the important role as a technique of patterning the Si and SiO₂ layers and the Al-based wiring film. During etching, the layers of Si, SiO2, Al, or the like react with ions and neutral radicals made from chlorine, bromine, or fluorine containing gases. Reaction products generated in the reaction are exhausted from a pumping port.

Materials of Cu, Pt, Fe or the like, which are expected to be introduced in the coming years, have low reactivity with halogen gases, and their halides as reaction products have low vapor pressures. In other words, those materials (non-volatile materials) are characterized by their low etching rates, and the extremely high adherability of their reaction products.

FIG. 2 is a diagram showing vapor pressures of halides of indium and tin as the metal elements used in the transparent conductive film ITO (indium tin oxides) on the display device, and so on. As shown in FIG. 2, in the case of tin, its chloride (SnCl₄) has a vapor pressure of 10 Torr or higher at normal temperature. Therefore, when etching the tin, it is possible to use a chlorine plasma to produce Sn chloride from the tin (Sn), and exhaust the Sn chloride gas from the reaction chamber. For this reason, tin may be classified as a volatile material.

On the other hand, in the case of indium, in order to obtain a vapor pressure of 10 Torr by indium chloride, it is necessary to heat it to 650K, that is, about 400° C. More specifically, it is difficult to exhaust indium chloride in the form of a gas. Therefore, ITO is classified as a non-volatile material.

Take alumina (Al₂O₃) for example, a chloride of Al as a possible product species of alumina has a high vapor pressure; however, because alumina itself is fairly stable, even if etching is performed using a chlorine gas, alumina is not expected to exhibit reactivity with chlorine. Moreover, reaction products are not dissolved sufficiently, with the result that aluminum is not necessarily exhausted as aluminum chloride from the reaction chamber. Therefore, materials such as alumina are classified as non-volatile materials.

As shown in FED Review Vol. 1, No. 26, 2001, for example, an etching technique is well known which uses gases of CO/NH₃, for example, in etching of a Fe-based material, and produces as a reaction product a carbonyl compound gases Fe(CO)x, which has a vapor pressure higher than chlorides. In other words, the carbonyl compound gases may be exhausted by changing gases used. However, even if the gases mentioned above are used, the reactivity between the gas and the etching material is not as high as in etching of aluminum by chlorine.

In this specification, let materials be defined as non-volatile materials if the vapor pressure of their reaction products is lower by not less than three orders of magnitude than that of SiCl₄, the SiCl₄ being a typical reaction product when Si or SiO₂, the most common material, is etched.

It has been well known that to etch those non-volatile materials, it is effective to make ions at a high bias potential strike a processing object and keep it at high temperature to promote the sublimation of reaction products. The fact that a thin Cu film, for example, could be etched by heating it at about 350° C. while using a mixed gas of CCl4 and N2 has been reported in 36^{th} Japan Applied Physics Meeting (1989 Spring) Scheduled Papers p.570, Lecture No. 1p-L-1. According to this paper, by carrying out etching of Cu by a sputtering-etching by ions at high energy and keeping the etching material at high temperature, chlorides of Cu as reaction products are prevented from being deposited again on the surface of the etching material, and thus a non-volatile material such as Cu can be etched.

### SUMMARY OF THE INVENTION

As has been described, it has been confirmed at experiment and trial production levels that non-volatile materials can be patterned by plasma etching under process conditions of high temperature and high bias potential. New LSI devices using those materials are being produced in trial production levels. However, it is not easy to realize plasma etching of such non-volatile materials at the mass-production stage. More specifically, the vapor pressure of reaction products generated when any of those non-volatile materials is subjected to a plasma etching process is very low, and therefore their reaction products are not exhausted from the chamber by the pump and a large portion of them are deposited on the walls of the chamber.

The deposition of the reaction products, even if it is not a big problem in the experiment and trial production levels, becomes a serious problem on the LSI production line. In the etching process of those materials, a deposited film of reaction products grows to a substantial thickness on the chamber walls only after several or tens of wafers have been processed. In such a case, the plasma condition changes or particles are produced to such an extent that the etching process cannot be continued any longer. Therefore, in an effort to implement non-volatile-material etching apparatus applicable to the mass production line, it matters much how to cope with the deposited film mentioned above.

The present invention has been made with the above problem in mind and has as its object to provide a plasma processing method and apparatus for etching non-volatile materials, which is capable to be used in mass-production lines.

According to an aspect of the present invention, there is provided a plasma processing apparatus having a process chamber, a gas feeding pipe for introducing a processing gas into the process chamber, a wafer-holding electrode for receiving and holding a sample located in the process chamber, a radio frequency power source for generating a bias potential to supply the bias potential to the sample, and an induction coil for supplying a radio frequency power to the processing gas to produce a plasma, wherein the process chamber comprises a conductor member, disposed to face a portion of the internal surface of the process chamber, for supplying a bias potential to that portion, and a detachable deposition trap member having a surface for deposition of reaction products formed at another portion of the internal surface of the process chamber.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram for explaining plasma processing apparatus according to an embodiment of the present invention;

FIG. 2 is a diagram showing vapor pressures of halides of tin and indium;

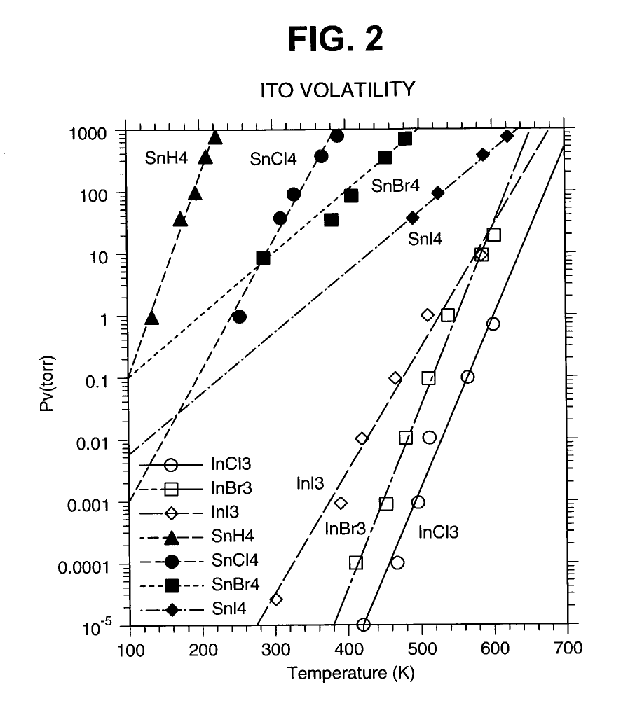

FIG. 3 is a diagram for explaining the shape of an insulator member;

FIG. 4 is a diagram for explaining another example of the shape of the insulator member;

FIG. 5 is a diagram for explaining an arrangement example of the conductor member;

FIG. 6 is a diagram for explaining the arrangement of the insulator member and the induction coil;

FIG. 7 is a diagram for explaining another example of the arrangement of the insulator member and the induction coil;

FIG. 8 is a diagram for explaining another example of the induction coil;

FIG. 9 is a diagram for explaining details of the conductor member;

FIG. 10 is a diagram for explaining the etching rate/the deposition rate of the insulator member;

FIG. 11 is a diagram for explaining the structure of the deposition trap member;

FIG. 12 is a diagram for explaining another structure of the deposition trap member;

FIG. 13 is a diagram for explaining yet another structure of the deposition trap member;

FIG. 14 is a diagram for explaining a further structure of the deposition trap member;

FIG. 15 is a diagram for explaining a still further structure of the deposition trap member;

FIG. 16 is a diagram for explaining the surface of the chamber covered by the conductor member and the surface covered by the deposition trap member;

FIG. 17 is a diagram for explaining a method for controlling the adhering mass of reaction products at the deposition trap member;

FIG. 18 is a diagram for explaining another method for controlling the adhering mass of reaction products at the deposition trap member; and

FIG. 19 is a diagram for explaining yet another method for controlling the adhering mass at the deposition trap member.

### DETAILED DESCRIPTION OF THE EMBODIMENTS

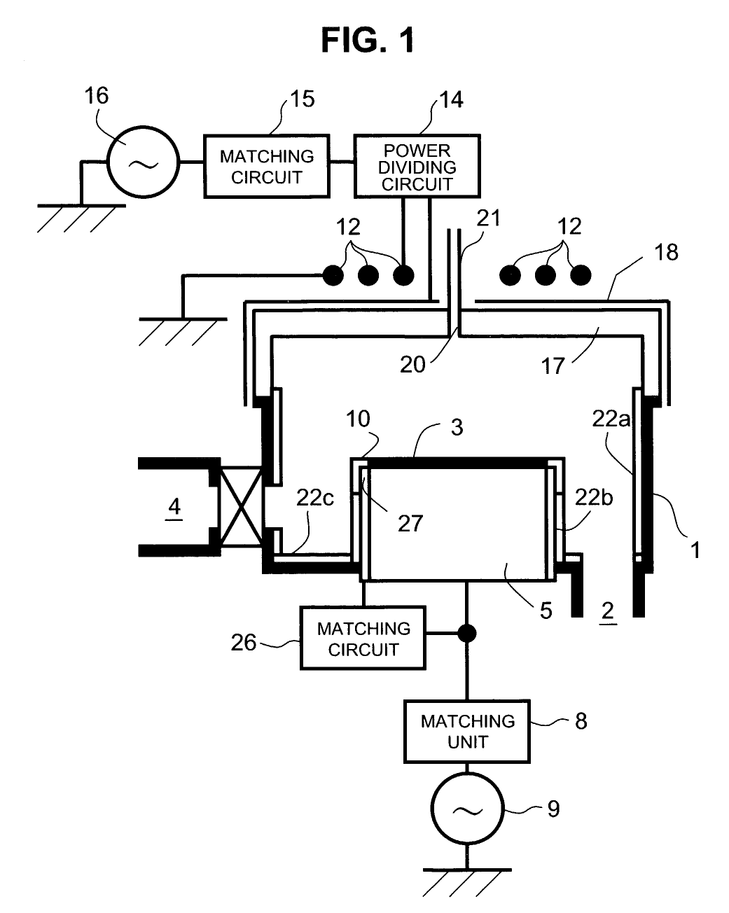

An embodiment of the present invention will be described with reference to the accompanying drawings. FIG. 1 is a diagram for explaining plasma processing apparatus according to an embodiment of the present invention. In FIG. 1, a process chamber 1 is a vacuum vessel made of aluminum coated with anodized aluminum or made of stainless steel, and the vessel is electrically connected to ground. The process chamber 1 comprises a vacuum pumping means 2, and a transfer system 4 to carry in and out a wafer 3 as a processing object. In the process chamber 1, there is provided a wafer-holding electrode 5 on which a wafer 3 is loaded. The system 4 sends the wafer into the process chamber and places the wafer on the wafer-holding electrode 5. The wafer-holding electrode 5 holds a wafer by electrostatically chucking it by an electrostatic chuck, not shown.

The wafer-holding electrode 5 is connected through a matching unit 8 to an RF power source 9 which output frequency varies from several hundreds of KHz to several tens of MHz. By adjusting the output of the power source, the energy of ions incident onto the semiconductor wafer 3 can be controlled during the plasma process. The wafer is heated or cooled at a desired temperature during etching by temperature control system which is not shown in the figure. On the top surface of the electrode other than the wafer-mounting area of the wafer-holding electrode 5, a susceptor 10 of insulating material is provided to protect the wafer-holding electrode from the plasma and the reactive gas.

A plasma source is located at that position of the process chamber 1 which faces the wafer 3. FIG. 1 shows a case where inductively-coupled plasma is used as the plasma source. As shown in FIG. 1, an induction coil 12 is arranged to face the wafer 3 on the atmosphere side of a domed insulator member 17 made of an insulating material, such as quartz or alumina ceramics.

A conductor member 18 is disposed between the induction coil 12 and the insulator member 17. The conductor member 18 made of a metal sheet having radial slits, which will be described later, is formed to completely cover the domed insulator member 17. Those slits are formed radially in such a way as to go across the coiled conductor 12. This arrangement is intended so that the induced currents produced by the currents flowing through the induction coil may not be inhibited from flowing into the plasma. A power supply line is lead out of the center of the induction coil, and this power supply line is connected to a radio-frequency power source 16 from several hundreds of KHz to several tens of MHz through a power dividing circuit 14 and a matching circuit 15. An inlet 20 of the processing gas is provided almost at the center of the domed insulator member 17 at the top of the process chamber. The processing gas is introduced into the chamber through the feeding pipe 21 and the gas inlet 20. It ought to be noted that the whole process chamber 1 should preferably be controlled in temperature by a temperature regulator, not shown.

As described previously, the power generated by the radio-frequency power source 16 is supplied to the induction coil 12 and the conductor 18. The induction coil 12, as it is electromagnetically coupled with the plasma, produces a high-frequency inductively coupled plasma with high energy density. The conductor member 18, by an RF field it generated, draws ions of the plasma generated by the induction coil 12 into the surface of the process chamber 1. Therefore, by changing the RF voltage generated at the conductor member 18 by controlling the power supplied to the conductor member 18, the energy of ions incident on the domed insulator member 17 can be controlled.

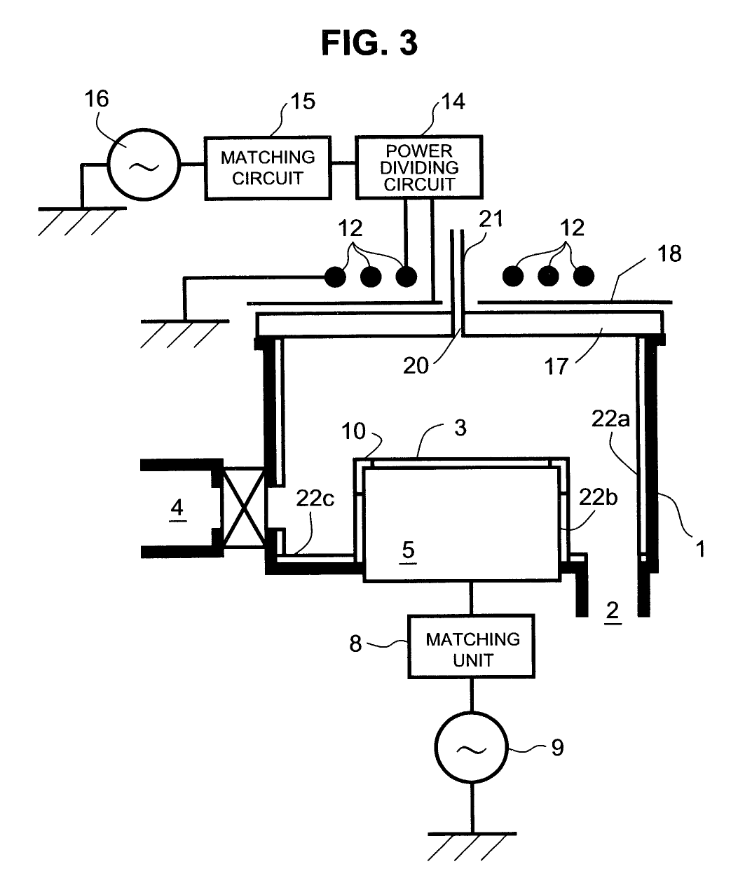

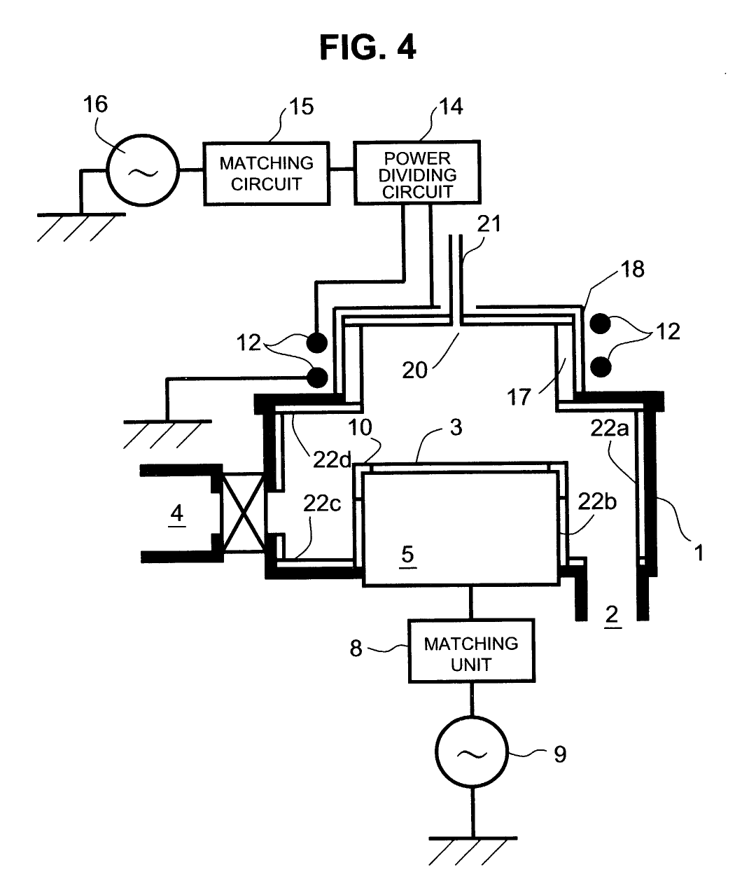

Note that the domed insulator member 17 is used in the example in FIG. 1. However, the insulator member 17 may be formed in a flat plate type as shown in FIG. 3, or it may be formed in a cylindrical shape as shown in FIG. 4. In the latter case, the induction coil 12 is disposed around the side wall of the cylindrical insulator member 17.

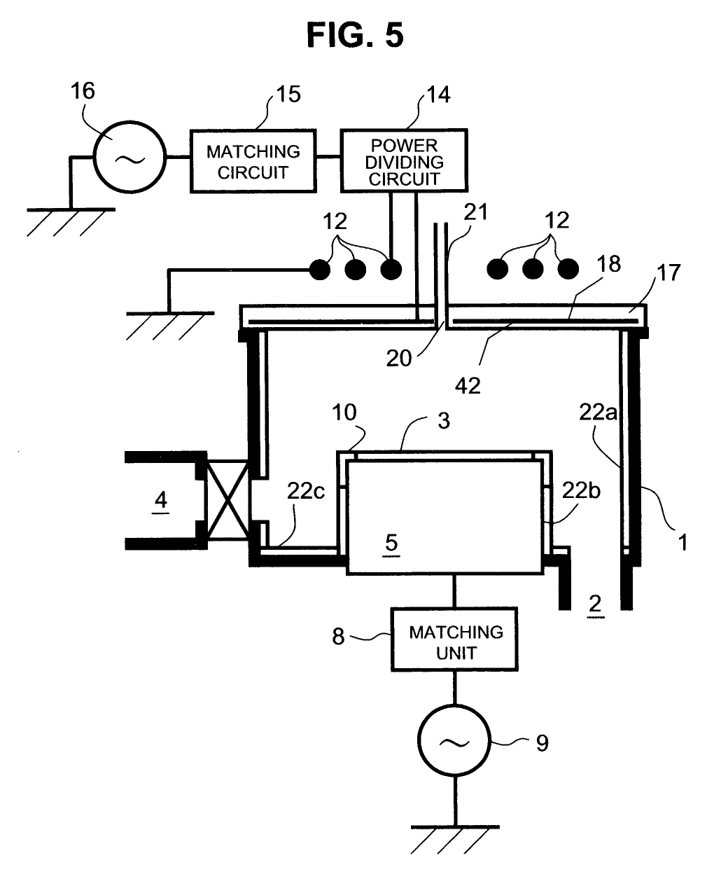

Description will now be made of the arrangement of the conductor member 18. In the example shown in FIG. 1, the conductor member 18 is disposed on the atmosphere side of the domed insulator member 17. However, the conductor member 18 may be installed on the vacuum side of the insulator member 17 as shown in FIG. 5. In this example, however, it is preferable to provide an insulating cover 42 to protect the conductor member 18 disposed on the vacuum side (inside the process chamber) from a corrosive gas or plasma.

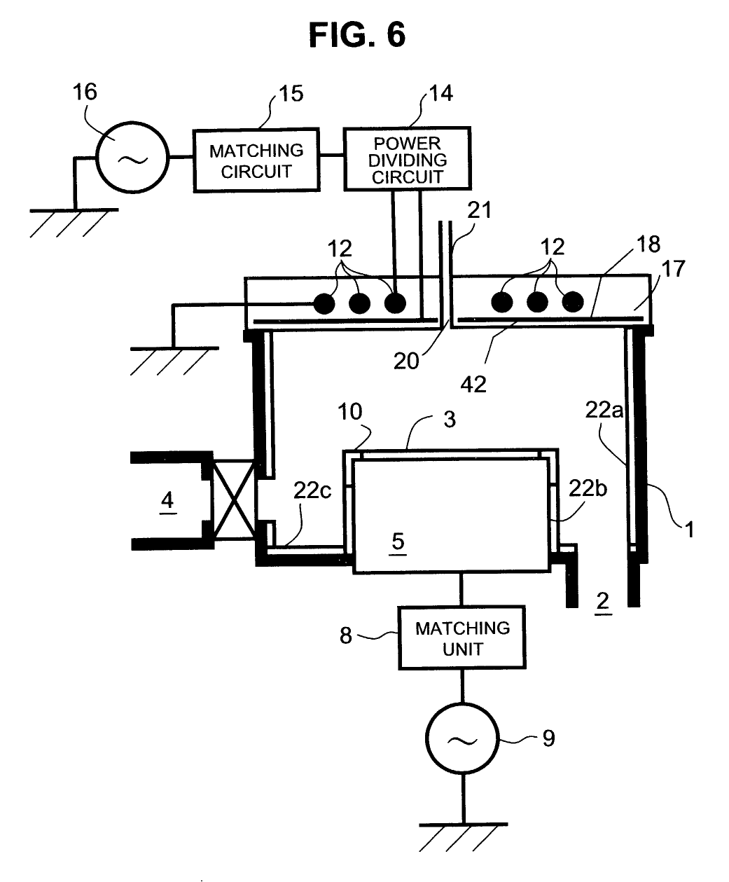

When the conductor member 18 is mounted on the vacuum side of the insulator member 17 as shown in FIG. 5, the induction coil 12 may be arranged on the vacuum side or may be embedded in the insulator member 17 as shown in FIG. 6.

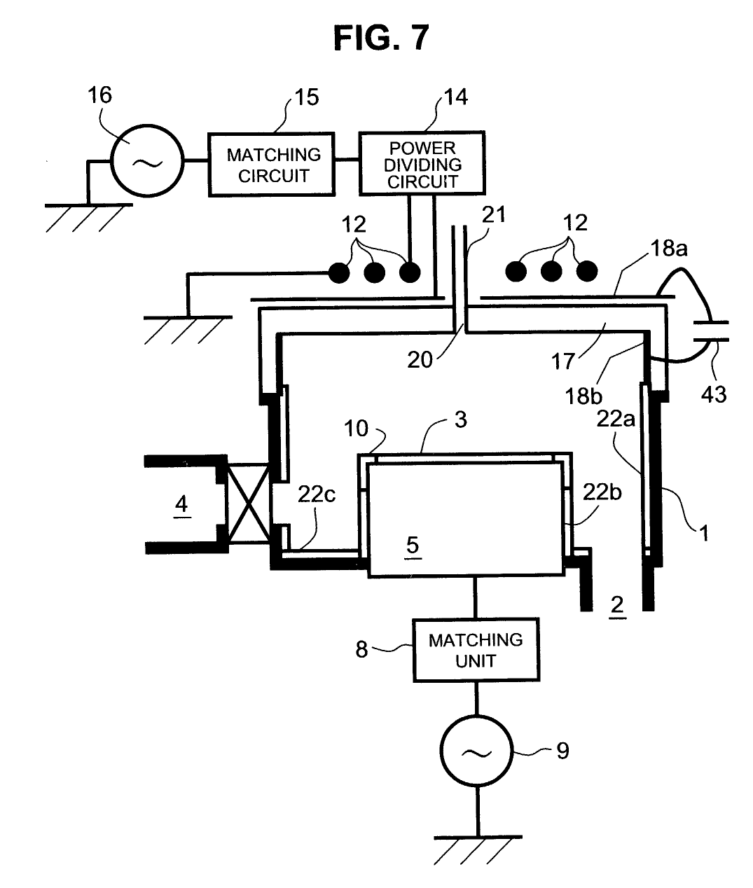

As shown in FIG. 7, a portion 18a of the conductor member 18 may be mounted on the atmosphere side of the insulator member 17, and the remainder 18b of the conductor member 18 may be mounted on the vacuum side of the insulator member 17. Even though the same voltage is applied to the conductor member 18, the effect of the electric field by the portion 18a disposed on the atmosphere side remote from the plasma is smaller than that of the remainder 18b. Therefore, it is desirable to form a circuit such that the voltage is made higher on the portion 18a than on the remainder 18b of the conductor cover by connecting the portion 18a and the remainder 18b of the conductor member across a capacitor of a suitable value.

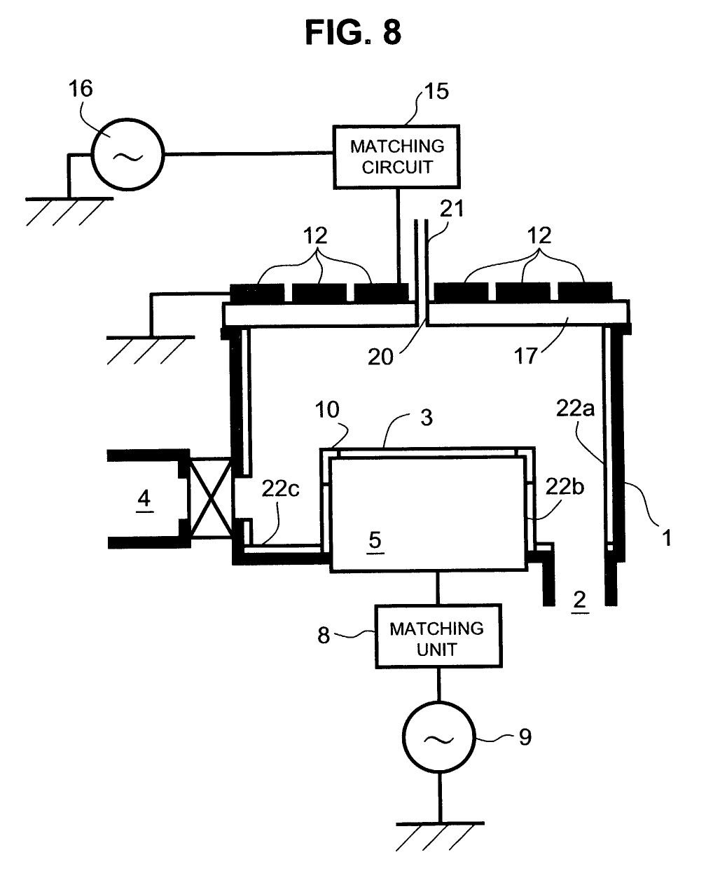

As shown in FIG. 8, the induction coil 12 may be formed in a flat shape, and this flat coil is arranged close to the insulator member 17. Under this arrangement, the flat induction coil 12 can be utilized as the conductor member 18 to which power generated by the induction coil 12 and the RF power source 16 is supplied. Therefore, in this case, the conductor member 18 and the power dividing circuit 14 shown in FIG. 1 can be done away with. However, in this instance, though the apparatus can be formed in a simpler configuration, it is impossible to control the plasma density and the incident ions independently of each other.

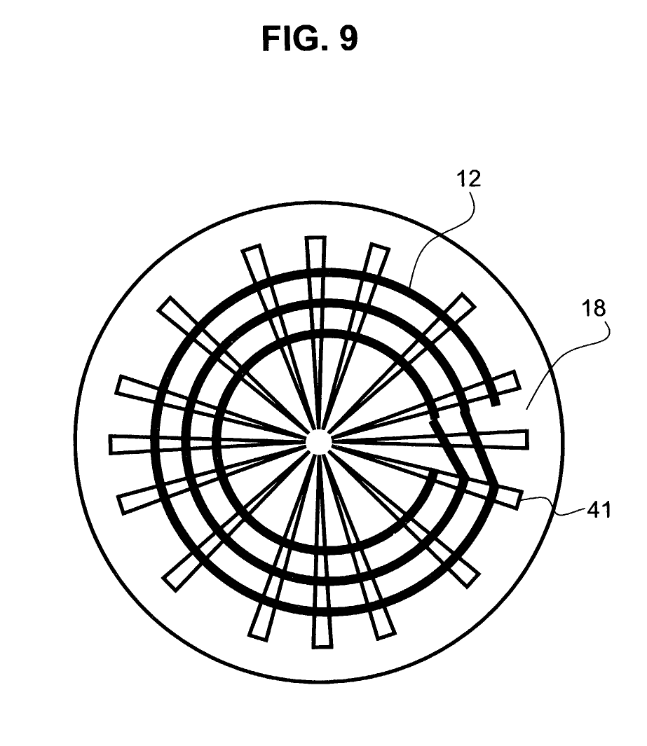

FIG. 9 is a diagram for explaining details of the conductor member 18 mentioned above. As shown in FIG. 9, the conductor member 18 made of metal sheet having radial slits formed therein covers the domed insulator member 17. The induction coil 12 is arranged on the top surface of the conductor member 18.

Description will move on to a method for keeping clean the surface of the insulator member 17 by using the conductor member 18.

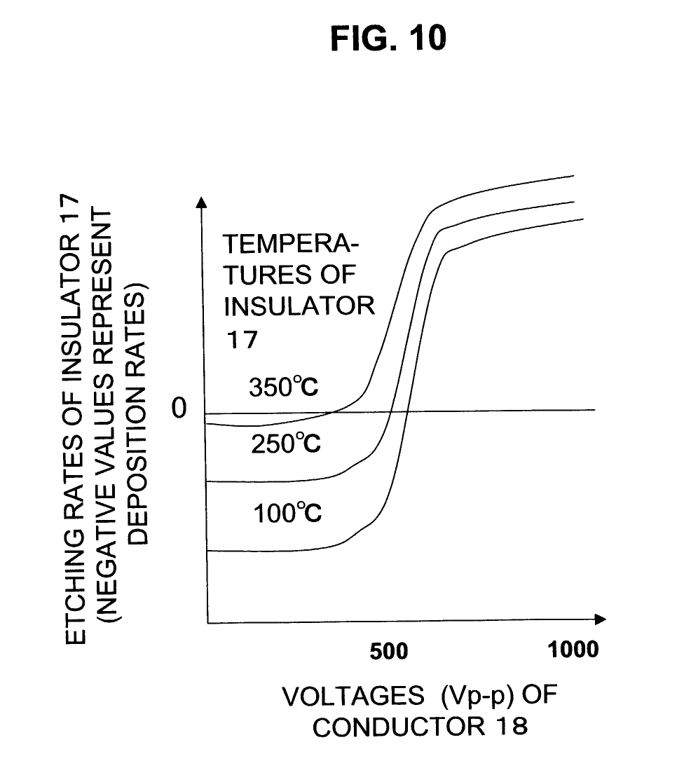

FIG. 10 is a diagram showing the etching rates/deposition rates of the insulator member 17 when platinum is etched by chlorine-gas plasma under specified conditions, by using the temperature of the insulator member 17 as a parameter. As shown in FIG. 10, if the temperature of the insulator member 17 is 100° C., when the voltage applied to the conductor member 18 is low, reaction products produced by etching of platinum are deposited on the surface of insulator member 17. As the applied voltage is increased, the surface of the insulator member 17 shifts over to its being etched at about 500 Vp-p (high frequency peak-peak voltage value) as the threshold value. By supplying a voltage of not less than 500 Vp-p, the surface of the insulator member 17 can be kept clean even in etching of platinum under the above-mentioned specified conditions, but the effect may vary to some extent dependent on the kind and the thickness of the insulating material.

If the temperature of the insulator member 17 is raised to 350° C., the deposition of reaction products can be almost prevented even when the voltage applied to the conductor member 18 is low. However, in view of the reliability of the vacuum sealing between the insulator member 17 and the vacuum chamber 1, for example, there is a limit to adhesion prevention of deposits because of increases in temperature. Therefore, to keep clean the surface of the insulator member 17, a method of applying a bias potential according to the present invention is more suitable for use on the mass-production line.

Description will next be made of a method for keeping clean the surface of the susceptor 10. The susceptor 10 is located very close to a wafer, and when a thick deposited film grows on the susceptor surface, a large amount of particles is produced.

Description will be made of a method of keeping clean the surface of the susceptor by using a wafer bias with reference to FIG. 1. As shown in FIG. 1, output of the RF power source 9 for wafer bias is applied to a bias-applied part 27 for the susceptor mounted on the side wall of the electrode through the intermediary of the matching box 8 and the power dividing circuit 26. By controlling the power applied to the bias-applied part 27, as in the case of the insulator member 17, the energy of the ions incident onto the surface of the susceptor 10 can be controlled to thereby prevent reaction products from being deposited on the susceptor 10. Incidentally, by having the thickness of the susceptor 10 adjusted so that a voltage may be produced also on the susceptor surface within a range of the bias power condition applied in etching of an actual wafer, reaction products can be prevented from being deposited on the susceptor 10 without providing a special piece of hardware, such as the power dividing circuit.

Description has been made of how to keep clean the surfaces of the insulator member 17 and the susceptor 10 by controlling the energy of ions incident onto those devices. However, even if one could successfully prevent the deposition of reaction products on the surfaces of the insulator member 17 and the susceptor 10, because the vapor pressure of the reaction products in the etching process of a non-volatile material is low, the reaction products cannot be exhausted even by an exhaust pump. After all, the reaction products are deposited on the other areas in the process chamber.

Therefore, according to the present invention, a part 22 (the trap member) is installed downstream of the process chamber for the reaction products to be deposited to it.

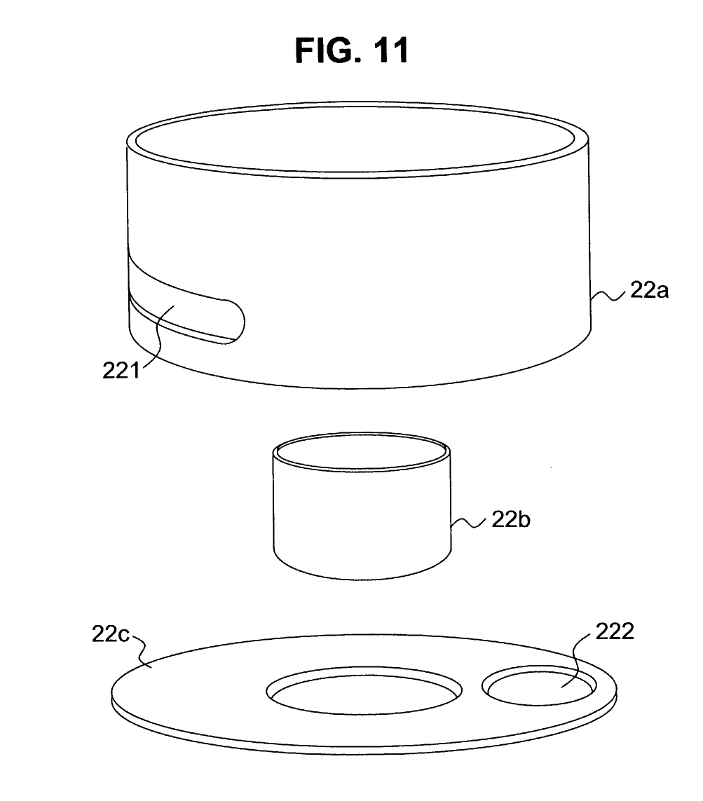

FIG. 11 is a diagram for explaining the structure of the trap member. The trap member 22 includes an outer cylinder 22a to cover the internal wall of the process chamber, an inner cylinder 22b to cover the external wall of the wafer-holding electrode, and a bottom plate 22c to cover the bottom portion of the process chamber. A through-hole 221 through which to carry a wafer in and out and an exhaust slot 222 are provided in the outer cylinder 22a and the bottom plate 22c, respectively.

As shown in FIG. 11, the trap member is formed in an easily detachable structure, so that it can be changed with a clean trap member, for example, in maintenance service, which contributes to reductions of downtime. The trap member may be made of a metallic material, such as aluminum or stainless steel or an insulating material, such as quartz, and is structured to substantially cover the main surfaces in the process chamber (except for the insulator member 17 and the top portion of the wafer-holding electrode (the wafer-mounting area and the susceptor 10)).

The trap member should preferably have a surface of an up-and-down structure for better adherability of reaction products. According to results of an experiment by the present inventors, the surface roughness (Ra) of the trap member should preferably be 10 μm or larger in conjunction with etching reaction products of a non-volatile film. Therefore, the surface of the trap member may effectively be roughened by shot blasting. There is a limit to the thickness of deposits that can be held on the surface of the trap member. (Deposits, if grown to a greater thickness, may fall off.) In this respect, the larger surface area, in a macro sense, of the trap member is better. And, increasing the surface area within a range that does not inhibit gas emission is effective for prolonging the service life of the trap member.

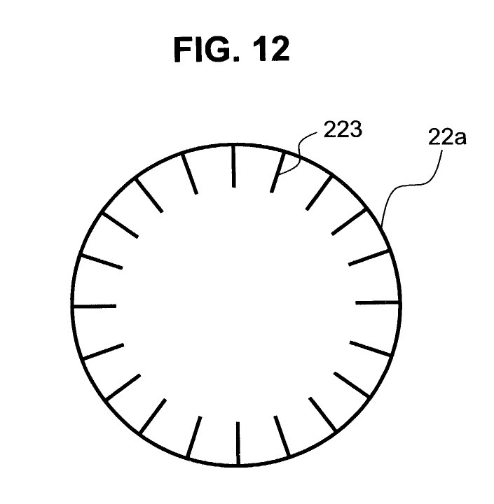

FIG. 12 is a diagram showing another example of the structure of the trap member. As shown in FIG. 12, multiple fins are provided on the internal surface of the outer cylinder 22a.

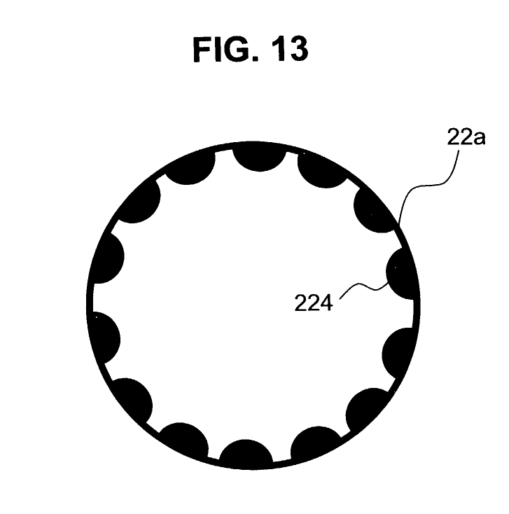

FIG. 13 is a diagram showing yet another structure of the trap member. As shown in FIG. 13, undulations 224 are provided on the internal surface of the outer cylinder 22a. Those undulations may be formed as points or in a continuous wavy line.

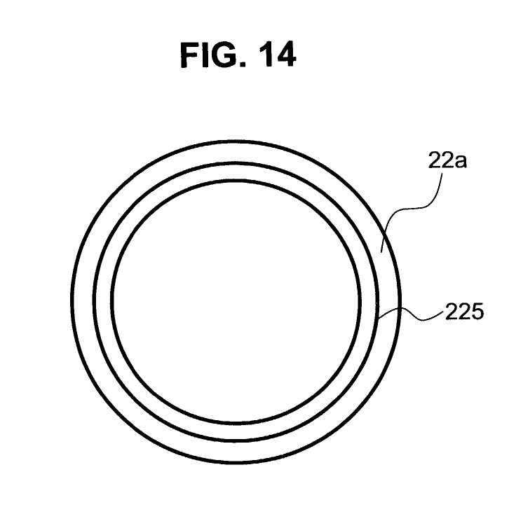

FIG. 14 is a diagram showing a still further structure of the trap member. As shown in FIG. 14, cylindrical parts 225 are mounted concentrically within the outer cylinder 22a. This structure facilitates handling (particularly in washing with a chemical solution) in maintenance service.

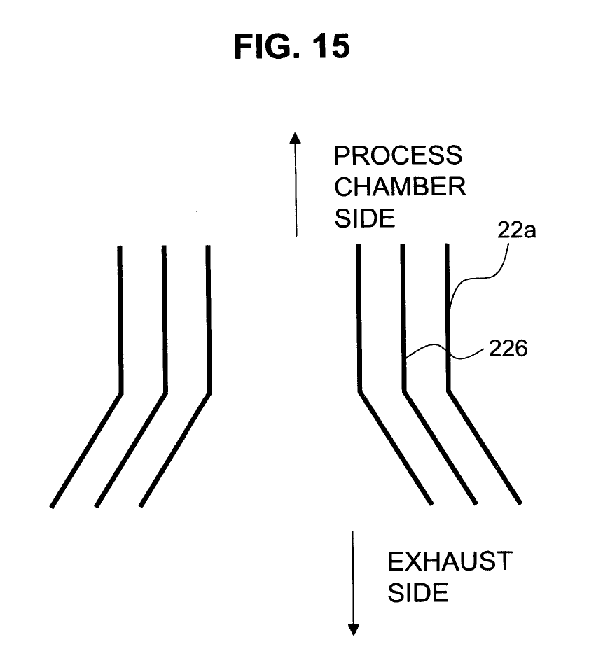

FIG. 15 is a diagram showing an additional structure of the trap member. As illustrated, the outer cylinder 22a is formed like a funnel to broaden out on the downstream side, and funnel-like components 226 that also broaden out on the downstream side are mounted concentrically within the outer cylinder 22a. Because the funnel-like components 226 are installed, that portion of the chamber which is downstream of the trap member is covered from the electric discharge space, reaction products can be prevented from being deposited on the downstream area of the chamber.

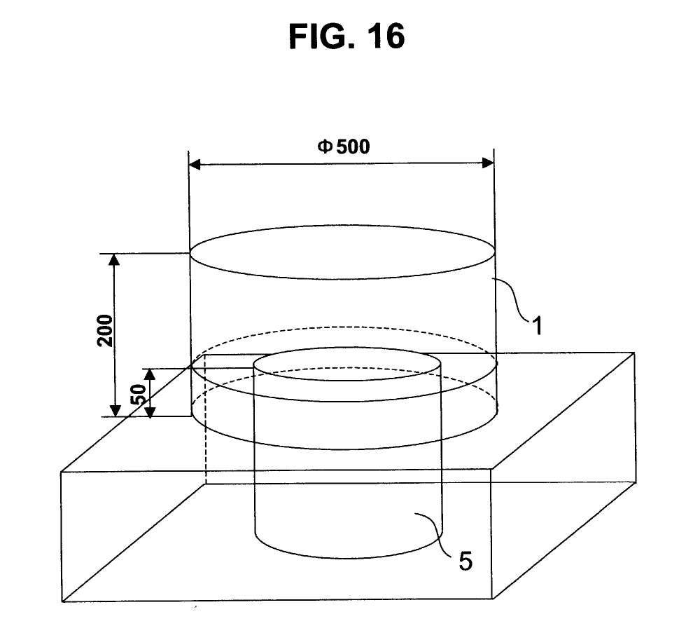

FIG. 16 is a diagram for explaining a surface covered by the conductor member and another surface covered by the trap member out of the internal surfaces of the process chamber 1.

As described above, the etching of non-volatile materials can be achieved on a mass-production level by supplying an RF bias to the insulator member 17 through the conductor member, by optimizing the thickness of the susceptor 10 and supplying an RF bias to the susceptor, for example, or by mounting the trap member 22.

There are those parts which cannot be protected by the trap member or the conductor member, such as the openings, like the hole 221 to carry in and out a wafer and the exhaust hole 222, but the other parts should preferably be the parts that receive an RF bias (wall bias) supplied by the conductor member and also the parts covered by the trap member.

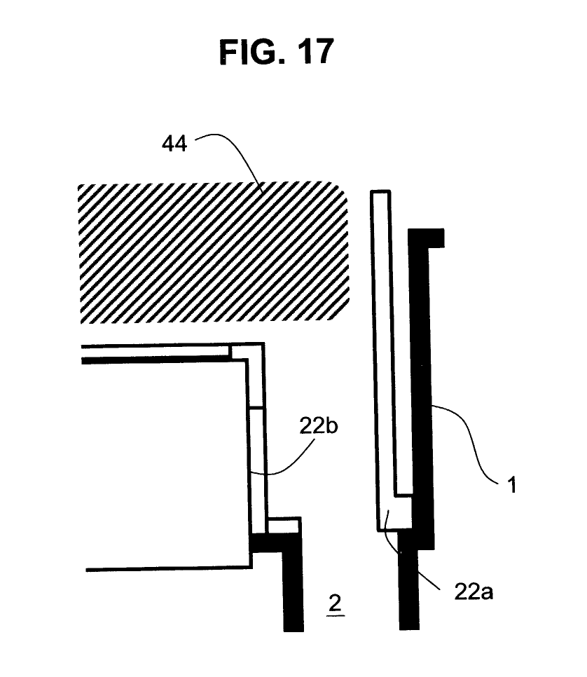

Referring to FIG. 16, if the process chamber is defined as a plasma generating space extending from the top surface of the wafer-holding electrode 5 upward (the space of φ500 mm×150 mm open to the insulator member 17 as shown in FIG. 17), out of all internal walls of that space formed by the chamber 1 and the wafer-holding electrode 5 and so on, not less than 90% of those walls should preferably be either a biased surface that can control the ion energy by controlling the RF bias potential, or the detachable trap member.

In the plasma processing apparatus shown in FIG. 1, the density of reaction products in the process chamber is the highest in the area above the top of the wafer-holding electrode 3. For this reason, reaction products are deposited in large amounts in the neighborhood of the top end of the outer cylinder 22a of the trap member, and therefore the replacement frequency of the trap member is determined by the deposits on the above-mentioned portion of the outer cylinder.

FIG. 17 is a diagram for explaining the method for controlling the controlling mass of reaction products on the trap member. By providing a gap between the outer cylinder 22a of the trap member and the process chamber 1 to separate the upper portion of the trap member from the wall of the process chamber 1, the upper portion of the outer cylinder 22a is thermally insulated from the process chamber 1. The outer cylinder 22a is heated by the plasma 44 generated in the process chamber 1. At this time, because the plasma density is high in its upper portion, the outer cylinder 22a of the trap member has a temperature distribution showing that the temperature is high at its upper positions, and reaction products are prevented from being deposited at the upper positions of the outer cylinder 22a unlike in FIG. 3.

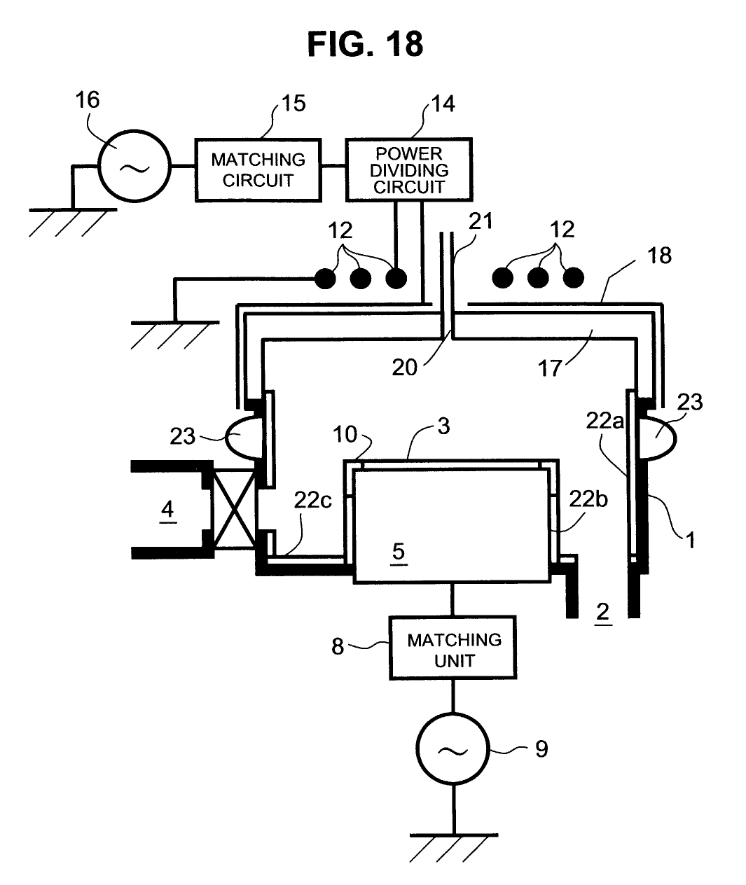

FIG. 18 is a diagram for explaining another method for adjusting the adhering mass of reaction products on the trap member. As shown in FIG. 18, the upper portion of the outer cylinder 22a of the trap member is kept at a predetermined temperature by heating that portion with a heating part 23, such as a halogen lamp. In this manner, reaction products can be prevented from being deposited on the upper portion of the outer cylinder 22a.

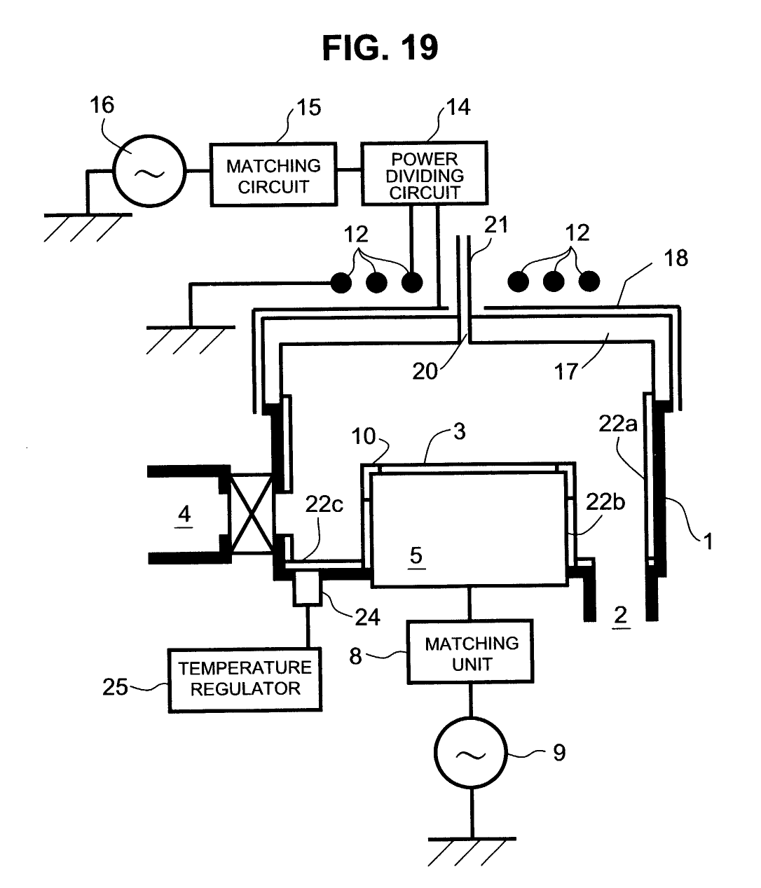

FIG. 19 is a diagram for explaining a still further method for controlling the adhering mass of reaction products on the trap member. In FIG. 19, the outer cylinder 22a, the inner cylinder 22b, and the bottom plate 22c each incorporate a sheathed heater and a temperature sensor, both not shown. A temperature regulator 25 supplies power to the outer cylinder 22a, the inner cylinder 22b, and the bottom plate 22c of the trap member through a feed-through capacitor 24 so that they are heated to predetermined temperatures. Therefore, the deposition of reaction products can be prevented from concentrating on specific places, and the replacement frequency of the trap member is prevented from determining the deposits on such places.

As has been described, according to this embodiment, reaction products are prevented from being deposited on some portion of the internal surfaces of the process chamber, which is necessary to keep the process taking place in a fixed operation and which could otherwise be the cause of inhibiting the process by generated particles, but on the other hand reaction products are made to be deposited on a replaceable part that does not affect the process at all. Therefore, it is possible to secure the high process stability and realize easy maintenance.

The present invention is not limited to the field of semiconductor device fabrication, but can be applied to the manufacture of liquid crystal displays, film deposition of various materials, or surface treatment. The present invention is effective not only for etchers of non-volatile materials but also for plasma CVD equipment which has to solve the problem of large amounts of deposits on the walls.

It is obvious from the forgoing description that the present invention makes it possible to provide plasma processing apparatus and a plasma processing method capable of stable etching of non-volatile materials.

It should be further understood by those skilled in the art that although the foregoing description has been made on embodiments of the invention, the invention is not limited thereto and various changes and modifications may be made without departing from the spirit of the invention and the scope of the appended claims.

What is claimed is:

1. A plasma processing apparatus comprising:
a process chamber;
a process gas feeding pipe for introducing a process gas into said process chamber;
a holding electrode for receiving and holding a sample placed in said process chamber;
a bias-potential-generating radio frequency power source for supplying a bias potential to said sample; and
an induction coil to produce a plasma, wherein said process chamber includes a conductor member, disposed to face a portion of an internal surface of said process chamber, for supplying a bias potential to said portion, and a detachable trap member having a surface for deposition of reaction products formed at another portion of said internal surface of said process chamber.

2. Apparatus according to claim 1, wherein said detachable trap member has a surface roughness of not less than 10 μm.

3. Apparatus according to claim 1, wherein a total of surfaces of said conductor member, said holding electrode having a bias applied thereto by a bias-applied part for a susceptor, a sample holding surface, and said trap member is not less than 90% of internal surfaces of a plasma generating space inside said process chamber.

4. A plasma processing apparatus comprising:
a process chamber;
a process gas feeding pipe for introducing a process gas into said process chamber;
a holding electrode for receiving and holding a sample placed in said process chamber;
a bias-potential-generating radio frequency power source for supplying a bias potential to said sample; and
an induction coil to produce a plasma, wherein said process chamber includes a conductor member, disposed to face a portion of an internal surface of said process chamber, for supplying a bias potential to said portion, and a detachable trap member having a surface for deposition of reaction products formed at another portion of said internal surface of said process chamber, said detachable trap member being capable of adjusting temperature.

5. Apparatus according to claim 4, wherein said detachable trap member has a surface roughness of not less than 10 μm.

6. Apparatus according to claim 4, wherein a total of surfaces of said conductor member, said holding electrode having a bias applied thereto by a bias-applied part for a susceptor, a sample holding surface, and said trap member is not less than 90% of internal surfaces of a plasma generating space inside said process chamber.

7. Apparatus according to claim 4, wherein said trap member comprises heating means for adjusting a temperature of said trap member.

8. For use with a plasma processing apparatus having a process chamber, a process gas feeding pipe for introducing a process gas into said process chamber, a holding electrode for receiving and holding a sample placed in said process chamber, a bias-potential-generating radio-frequency power source for supplying a bias potential to said sample, and an induction coil to produce a plasma, a method for processing said sample by supplying radio frequency power to said induction coil to make a plasma of said processing gas, wherein said process chamber comprises a conductor member for covering a portion of an inside wall of said process chamber and supplying bias potential to another portion of said inside wall of the process chamber corresponding to said portion, and a detachable trap member having a surface for deposition of reaction products formed in yet another portion of said inside wall of the process chamber, said method comprising the step of
changing said trap member every predetermined period.
